(19) United States
(12) Patent Application Publication
(10) Pub. No.: US 2026/0072350 A1
(43) Pub. Date: Mar. 12, 2026

(54) DETERMINATION OF A PROPERTY OF AN EXPOSURE LIGHT BEAM

(71) Applicant: Cymer, LLC, San Diego, CA (US)

(72) Inventor: Yingbo Zhao, San Diego, CA (US)

(21) Appl. No.: 18/709,099

(22) PCT Filed: Nov. 14, 2022
(86) PCT No.: PCT/US2022/049843

§ 371 Date: May 10, 2024

Related U.S. Application Data
(60) Provisional application No. 63/284,081, filed on Nov. 30, 2021.

(51) Int. Cl. G01N 21/33

(52) U.S. Cl. CPC G03F 7/2006; G03F 7/706

(57) ABSTRACT

An apparatus includes: an estimation system configured to: determine a set of values related to an initial light beam based on sensed wavefronts of the initial light beam, the set of values including a first value and a second value. The estimation system is also configured to determine an estimate of a property of an exposure light beam based on a non-linear relationship that includes the first value and the second value. The exposure light beam is formed by interacting the initial light beam with an optical system. The apparatus also includes a communications module coupled to the estimation system and configured to output the estimate of the property of the exposure light beam.

### CROSS REFERENCE TO RELATED APPLICATIONS

This application claims priority to U.S. Application No. 63/284,081, filed Nov. 30, 2021, titled DETERMINATION OF A PROPERTY OF AN EXPOSURE LIGHT BEAM, which is incorporated herein in its entirety by reference.

### TECHNICAL FIELD

This disclosure relates to determining a property of an exposure light beam. The exposure light beam may be generated based on an initial light beam that is emitted from a deep ultraviolet (DUV) optical source.

### BACKGROUND

Photolithography is the process by which semiconductor circuitry is patterned on a substrate such as a silicon wafer. An optical source generates deep ultraviolet (DUV) light used to expose a photoresist on the wafer. DUV light may include wavelengths from, for example, about 100 nanometers (nm) to about 400 nm. Often, the optical source is a laser source (for example, an excimer laser) and the DUV light is a pulsed laser beam. The DUV light from the optical source interacts with a projection optical system, which projects the beam through a mask onto the photoresist on the silicon wafer. In this way, a layer of chip design is patterned onto the photoresist. The photoresist and wafer are subsequently etched and cleaned. If needed, the photolithography process is repeated with a fresh photoresist.

### SUMMARY

In one aspect, an apparatus includes: an estimation system configured to: determine a set of values related to an initial light beam based on sensed wavefronts of the initial light beam, the set of values including a first value and a second value. The estimation system is also configured to determine an estimate of a property of an exposure light beam based on a non-linear relationship that includes the first value and the second value. The exposure light beam is formed by interacting the initial light beam with an optical system. The apparatus also includes a communications module coupled to the estimation system and configured to output the estimate of the property of the exposure light beam.

Implementations may include one or more of the following features. The property of the exposure light beam may be a convolved bandwidth metric, the convolved bandwidth metric representing a width of a portion of an optical spectrum of the exposure light beam at a wafer that is irradiated by the exposure light beam; and the optical spectrum of the exposure light beam includes intensity of the exposure light beam as a function of wavelength.

The sensed wavefronts of the initial light beam may include a fringe pattern produced from the initial light beam; the fringe pattern may include a plurality of fringes; the first value may include a first width of a first one of the plurality of fringes; and the second value may include a second width of a second one of the plurality of fringes. The first one of the plurality of fringes and the second one of the plurality of fringes may be the same one fringe. The first width may be a width of the one fringe at a first percentage of a peak intensity of the one fringe; and the second width may be a width of the one fringe at a second percentage of the peak intensity of the one fringe. The first percentage and the second percentage may be different percentages. The plurality of fringes may be concentric rings of light centered around a center point and separated by regions of no light; and the one fringe may be the fringe closest to the center point. The apparatus also may include an etalon configured to produce the fringe pattern.

The non-linear relationship may be a second-order relationship. One of the first value and the second value may be squared.

The non-linear relationship also may include a plurality of calibration parameters. The estimation system also may be configured to: access a reference value of the property of the exposure light beam; and determine values for each of the calibration parameters by minimizing a difference between the estimate of the property and the reference value of the property. The reference value of the property may be obtained by a spectrometer.

The apparatus also may include the optical system.

The optical system may include a projection lens and a reticle.

The apparatus also may include a detector configured to sense the wavefronts and to provide data related to the sensed wavefronts to the estimation system.

In another aspect, a system includes: a light source configured to emit a light beam that includes deep ultraviolet (DUV) light; an optical measurement system configured to produce a fringe pattern based on the light beam; a projection optical system configured emit an exposure light beam based on the light beam; and an estimation system configured to: determine a first value and a second value from the fringe pattern; and determine an estimate of a property of the exposure light beam based on the first value and the second value.

Implementations may include one or more of the following features.

The projection optical system may include a projection lens and a reticle.

The estimation system may be configured to determine the estimate of the property based on a non-linear relationship; and the non-linear relationship may include the first value, the second value, and a plurality of calibration constants. The estimation system also may be configured to: determine a value for each of the plurality of calibration constants based on minimizing a difference between the estimate of the property and a reference value of the property.

The optical measurement system may be an etalon.

The light source may include a master oscillator configured to emit a seed light beam, and a power amplifier configured to amplify the seed light beam to produce the light beam that includes DUV light.

In another aspect, a method includes: sensing wavefronts of an initial light beam; determining a set of values of an initial light beam based on the sensed wavefronts; determining a relationship that includes at least two of values in the set of values; and determining an estimate of a property of an exposure light beam based on the relationship. The exposure light beam is produced by interacting the initial light beam with an optical system.

The relationship may be a non-linear relationship.

Implementations of any of the techniques described above may include a system, a method, a process, a device, or an apparatus. The details of one or more implementations are set forth in the accompanying drawings and the description below. Other features will be apparent from the description and drawings, and from the claims.

### BRIEF DESCRIPTION OF THE DRAWINGS

FIG. 1A is a block diagram of an example of a system.

FIG. 1B shows an example of an interference pattern.

FIG. 1C is a block diagram of an image plane and an output lens of the system of FIG. 1A.

FIG. 2A is a block diagram of an example of an optical measurement apparatus.

FIGS. 2B and 2C relate to another example of an interference pattern.

FIG. 3 is a flow chart of an example of a process to determine an estimate of a property of the exposure light beam.

FIG. 4 is an example of experimental data showing convolved bandwidth (CBW) estimation error.

FIG. 5 is an example of experimental data showing error in CBW estimated from a second-order relationship as a function of a measured reference CBW.

FIG. 6 is an example of experimental data showing error in CBW estimated from a linear relationship as a function of a measured reference CBW.

FIG. 7A shows simulated data of estimated critical dimension (CD) as a function of an estimate of the 95% integral width (E95) for seven different exposure tools.

FIG. 7B shows simulated data of estimated critical dimension (CD) as a function of an estimate of full-width at half max (FWHM) for seven different exposure tools.

FIG. 7C shows simulated data of estimated critical dimension (CD) as a function of an estimate of CBW for seven different exposure tools.

FIGS. 8 and 10 show examples of deep ultraviolet (DUV) optical systems with which an optical measurement apparatus may be used.

FIG. 9 is an example of a projection optical system.

### DETAILED DESCRIPTION

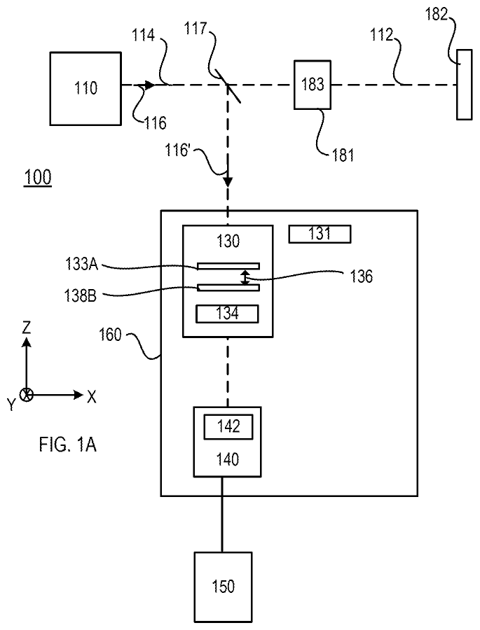

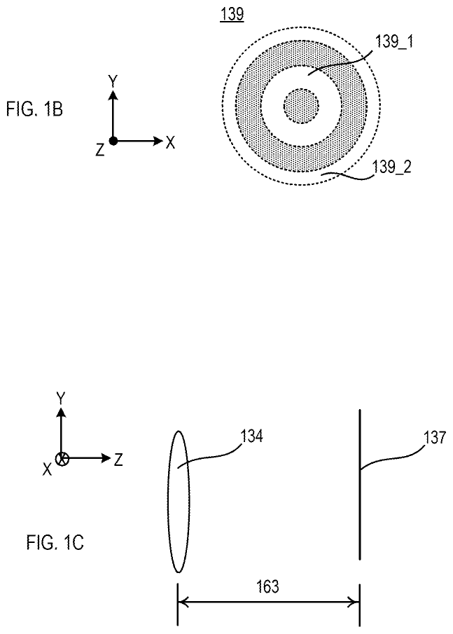

FIG. 1A is a block diagram of a system 100. In FIG. 1A, a dashed line between elements represents an optical path along which light travels and a solid line between elements represents a signal path along which information and/or data travels. The system 100 includes a light-generation module 110 that produces an initial light beam 116. The initial light beam 116 interacts with an optical system 181 to produce an exposure light beam 112. The optical system 181 includes components 183, such as, for example, one or more lenses, mirrors, apertures, and/or a reticle. The initial light beam 116 interacts with the components 183 by being, for example, reflected, refracted, and/or transmitted by the components 183 to produce the exposure light beam 112. The exposure light beam 112 exposes or irradiates an element 182 to form electronic features on the element 182. The element 182 may be, for example, a semiconductor wafer.

The system 100 includes an estimation system 150 that estimates a property of the exposure light beam 112. The property of the exposure light beam 112 may be, for example, a metric related to the spectral bandwidth of the exposure light beam 112. Before discussing the estimation system 150 in greater detail, an overview of the system 100 is provided.

The system 100 also includes a beam separator 117 that directs a portion 116′ of the initial light beam 116 to a measurement system 160. The beam separator 117 may be, for example, a beam splitter that directs the portion 116′ to the estimation system 150 and the remaining light in the initial light beam 116 to the optical system 181. In the example of FIG. 1A, the measurement system 160 includes an etalon 130 and a detector 140. The etalon 130 includes two parallel optical elements 133A, 133B, which are separated by a distance 136, and an output lens 134. The output lens 134 has a focal length 163, and the output lens 134 focuses incident light at an image plane 137. The image plane 137 coincides with an active region 142 of the detector 140. FIG. 1C is a block diagram that shows the image plane 137 and the output lens 134. The estimation system 150 is coupled to the measurement system 160. The estimation system 150 receives data from the detector 140.

Referring also to FIG. 1B, the output of the etalon 130 is a fringe pattern or interference pattern 139 that is focused at the image plane 137. FIG. 1B shows the interference pattern 139 in the image plane 137. In the example of FIG. 1B, the interference pattern 139 is a plurality of concentric rings of light that are formed at the image plane 137. Two fringes 139_1 and 139_2 are shown in FIG. 1B, but the interference pattern 139 may include additional fringes. The fringe 139_1 is a first order fringe, and the fringe 139_2 is a second order fringe, and the first and second order fringes 139_1, 139_2 are consecutive or adjacent fringes. With the arrangement shown in FIG. 1, the spatial distribution of the light in the interference pattern 139 depends at least in part on spectral properties of the light in portion 116′ of light beam 116.

The initial light beam 116 and the exposure light beam 112 each have an optical spectrum. The optical spectrum of a light beam contains information about how the optical energy, intensity, or power of the light beam is distributed over a range of wavelengths (or optical frequencies). The optical spectrum has a shape or profile as a function of wavelength. For example, the optical spectrum of the initial light beam 116 may have an approximately Gaussian shape as a function of wavelength. The spectral bandwidth of a light beam is representative of the range of wavelengths in the light beam.

Various metrics may be used to characterize the spectral bandwidth. Specific examples of metrics related to the spectral bandwidth include the full-width at half max (FWHM), which is the width of the optical spectrum at half of the maximum intensity of the optical spectrum, and the 95% integral width (E95), which is the interval of wavelengths that enclose 95% of the total energy in the optical spectrum. Other metrics may be used. For example, the spectral bandwidth may be expressed as a value that represents the range of wavelengths between the minimum and maximum wavelengths in the light beam.

The optical system 181 has a transfer function. The transfer function is a mathematical relationship that describes how the optical system 181 responds to inputs of various wavelengths. The shape of the transfer function as a function of wavelength depends on the characteristics (for example, size, orientation, materials, and/or shape) of the components 183 and the arrangement of the various components relative to each other.

The optical system 181 affects the spectral content of the initial light beam 116 such that the exposure light beam 112 generally does not have the same optical spectrum as the initial light beam 116. Mathematically, the optical spectrum of the exposure light beam 112 may be expressed as a convolution of the optical spectrum of the initial light beam 116 with the transfer function of the optical system 181. A convolution is a mathematical operation that expresses how the shape of a first function is modified by a second function to produce a third (or output) function. In this example, the optical spectrum of the exposure light beam 112 is the optical spectrum of the initial light beam 116 as modified by the transfer function of the optical system 181. In other words, the optical spectrum of the exposure light beam 112 is the convolution of the optical spectrum of the initial light beam 116 with the transfer function of the optical system 181.

The estimation system 150 estimates a spectral property of the exposure light beam 112 based on the fringe pattern 139. Although some legacy techniques use an interference pattern such as the fringe pattern 139 to determine properties of an optical light beam, the estimation system 150 provides additional and/or different information than these legacy approaches and also provides such information in a straightforward manner.

For example, some legacy systems determine the optical spectrum of the initial light beam 116 using a direct spectrum recovery approach. The direct spectrum recovery approach computes the optical spectrum of the initial light beam 116 from the fringe pattern 139. However, the computations involved in the spectrum recovery approach are complex and challenging. For example, the direct spectrum recovery approach involves inverting a matrix that represents the transfer function of the etalon 130, and this inversion may be complex and may cause large errors and noise when the matrix includes small values. Complex calculations may be particularly undesirable if they need to be performed repeatedly during operation (e.g., on a regular basis during operation of a laser). They may lead to slow operation speeds or they may require excessive computational resources. Moreover, the direct spectrum recovery does not provide spectral information about the exposure light beam 112 unless the computed spectrum of the initial light beam 116 is convolved with a mathematical function that represents the transfer function of the optical system 181. Furthermore, in some legacy systems, spectral bandwidth metrics such as the E95 and/or FWHM value of the optical spectrum of the initial light beam 116 are estimated using information from the fringe pattern 139 and a linear correlative technique.

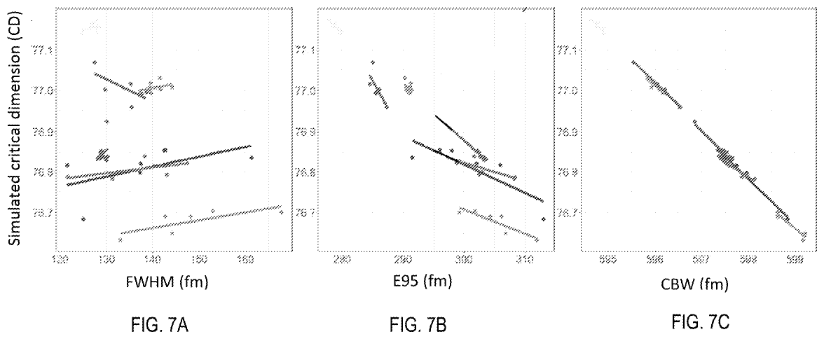

On the other hand, the estimation technique implemented by the estimation system 150 provides a straightforward and accurate approach for estimating a property of the exposure light beam 112 based on information related to the initial light beam 116. The convolved bandwidth (CBW) is an example of a property of the exposure light beam 112. The CBW is the FWHM of the optical spectrum of the exposure light beam 112. As shown in FIG. 7, the CBW has a strong correlation with critical dimension (CD), which is the smallest feature size that can be printed on the wafer 120 by the system 100. To maintain product uniformity and quality, it is desirable to maintain a consistent CD during use of the optical system 181 and also maintain a consistent CD among many instances of the optical system 181. Knowledge of the CBW provides insight into the CD for a particular optical system 181. Moreover, although each instance of the optical system 181 produces an exposure beam with unique properties, different exposure beams that have the same CBW are generally associated with the same CD. Accordingly, the CBW is a robust metric that may be used to characterize the exposure light beam 112 produced by the optical system 181. The CBW may also be a useful metric for exposure light beams produced by different instances of the optical system 181. The estimation system 150 estimates CBW of the exposure light beam 112 based on information related to the initial light beam 116. The estimates may also be based on characteristics of the optical system 181, such as a measured output through the optical system 181, or a modeled or measured transfer function of the optical system 181.

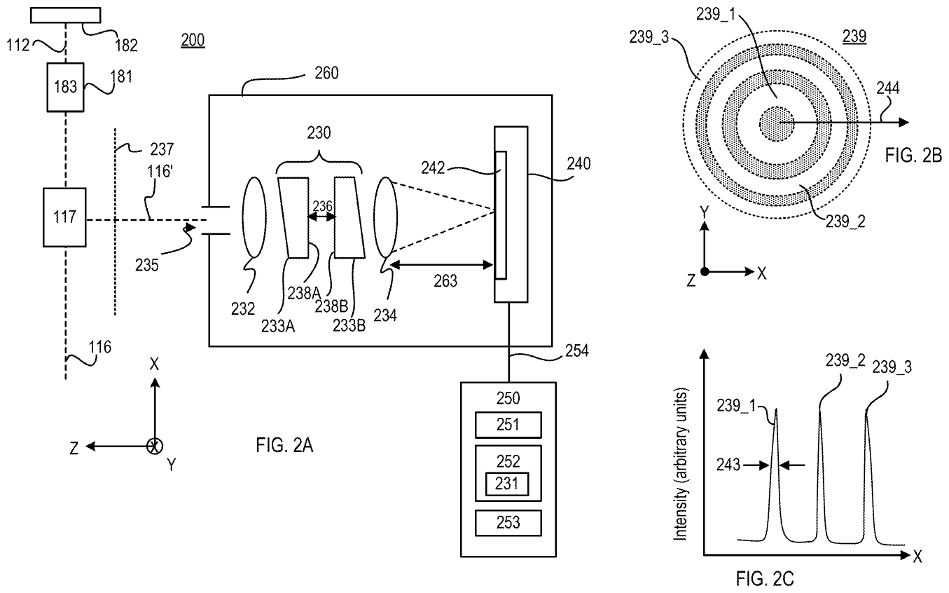

FIG. 2A is a block diagram of another system 200. The system 200 includes an estimation system 250, which is an example of an implementation of the estimation system 150 (FIG. 1A), and a measurement system 260. The measurement system 260 includes an input lens 232, an etalon 230, an output lens 234 (or focusing lens 234), and a detector 240. The portion 116′ is diffused and passes through an aperture 235 of the measurement system 260. The portion 116′ may be intentionally diffused by an optical diffuser (not shown) placed at a plane 237, which is between the beam separator 117 and the aperture 235. The aperture 235 is at a focal plane of the input lens 232. The input lens 232 collimates the portion 116′ before it enters the etalon 230. The output lens 234 has a focal length 263 and focuses light to an image plane. The detector 240 is positioned such that an active region 242 of the detector 240 coincides with the image plane.

In the example shown in FIG. 2A, the etalon 230 includes a pair of partially reflective optical elements 233A and 233B. The optical elements 233A and 233B are between the input lens 232 and the output lens 234. The optical elements 233A and 233B have respective reflective surfaces 238A and 238B that are spaced a distance 236 apart. The distance 236 may be a relatively short distance (for example, millimeters to centimeters). The optical elements 233A and 233B are wedged shape to prevent the rear surfaces (the surfaces opposite the surfaces 238A and 238B) from producing interference fringes. The rear surfaces may have an anti-reflective coating. Other implementations of the etalon 230 are possible. For example, in other implementations, the optical elements 233A and 233B are parallel plates and are not wedge-shaped. In yet another example, the etalon 230 may include only a single plate that has two parallel partially reflecting surfaces.

Referring also to FIG. 2B, the etalon 230 interacts with the portion 116′ and outputs an interference pattern 239. FIG. 2B shows the interference pattern 239 in the image plane of the lens 234 at an instance in time. The interference pattern 239 includes a plurality of fringes. Three of the plurality of fringes (239_1, 239_2, 239_3) are shown in FIG. 2B. The interference pattern 239 includes dark regions (with relatively less light or without light), created by destructive interference of the portion 116′, and bright regions (with relatively more light), created by constructive interference of the portion 116′. The regions of constructive interference are the fringes 239_1, 239_2, 239_3. The regions without light are shown with grey shading and are between the regions of light. The fringes 239_1, 239_2, 239_3 are concentric rings of light in the image plane of the output lens 234. Each ring in the set of fringes is an order (m) of the interference pattern, where m is an integer number equal to or greater than one. The fringe 239_1 is the first order fringe (m=1), the fringe 239_2 is the second order fringe (m=2), and the fringe 239_3 is the third order fringe (m=3). FIG. 2C is a graph of the intensity of the interference pattern 239 as a function of distance from the center of the interference pattern 239 along a path labeled 244 in FIG. 2B. The path 244 extends in the X direction from the center of the interference pattern 239. The FWHM of the fringe 239_1 at is labeled 243 in FIG. 2C.

The interference pattern 239 is sensed at the active region 242 of the detector 240. The detector 240 is any type of detector capable of sensing the light in the interference pattern 239. For example, the active region 242 may be a linear photodiode array that includes multiple elements of the same size arranged along a single dimension at an equal spacing in one package. Each element in the photodiode array is sensitive to the wavelength of the portion 116′. As another example, the detector 240 may be a two dimensional sensor such as a two-dimensional charged coupled device (CCD) or a two-dimensional complementary metal oxide semiconductor (CMOS) sensor.

The detector 240 is connected to the estimation system 250 via a data connection 254. The estimation system 250 includes an electronic processing module 251, an electronic storage 252, and an I/O interface 253. The electronic processing module 251 includes one or more processors suitable for the execution of a computer program such as a general or special purpose microprocessor, and any one or more processors of any kind of digital computer. Generally, an electronic processor receives instructions and data from a read-only memory, a random access memory (RAM), or both. The electronic processing module 251 may include any type of electronic processor. The electronic processor or processors of the electronic processing module 251 execute instructions and access data stored on the electronic storage 252. The electronic processor or processors are also capable of writing data to the electronic storage 252.

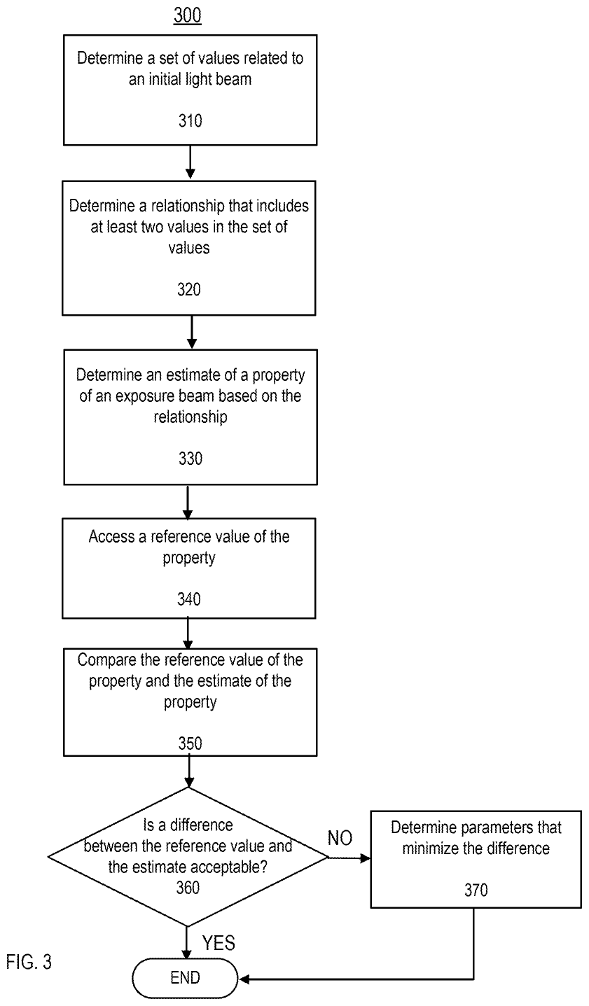

The electronic storage 252 is any type of computer-readable or machine-readable medium. For example, the electronic storage 252 may be volatile memory, such as RAM, or non-volatile memory. In some implementations, and the electronic storage 252 includes non-volatile and volatile portions or components. The electronic storage 252 may store data and information that is used in the operation of the estimation system 250. The electronic storage 252 also may store instructions (for example, in the form of a computer program) that cause the estimation system 250 to interact with the estimation system 250. For example, the instructions may be instructions that together form an estimation module 231 that, when executed, cause the electronic processing module 251 to implement the process 300 discussed with respect to FIG. 3. The electronic storage 252 also may store initial values of various calibration values used by the process 300.

The electronic storage 252 stores instructions that analyze data from the detector 240 to determine information about the initial light beam 116. For example, the electronic processing module 251 may be configured to determine values or indicators that relate to characteristics of the initial light beam 116. In some implementations, the electronic processing module 251 is configured to determine these values from the interference pattern 239. For example, the electronic storage 252 may store instructions that cause the electronic processing module 251 to determine a width of the fringe 239_1 and a width of the fringe 239_2, or two different widths of the fringe 239_1 or the fringe 239_2 or the fringe 239_3, or other combinations. The width of the fringe 239_1 may be determined by determining the FWHM 243 (FIG. 2C). Other widths of the fringe 239_1 may be determined. For example, the width of the fringe 239_1 at 0.1, 0.2, or 0.9 of the maximum intensity of the fringe 239_1 may be determined and stored as an indication or value related to the initial light beam 116. A another example, a width that contains some percentage (e.g, 10%, 50%, 95%) of the total light in the fringe 239_1 may be determined and stored as an indication or value related to the initial light beam 116. In another example, the maximum intensity of each fringe 239_1, 239_2, 239_3 is determined and used as the information related to the initial light beam 116.

The fringe 239_1 is the fringe closest to the center of the fringe pattern 239 and generally has the widest extent in the radial direction of all of the fringes in the fringe pattern 239. Thus, using data from the fringe 231_1 may provide a higher resolution and greater accuracy than data from other fringes in the pattern 239. Moreover, although complete fringes are shown in the fringe pattern 239, in some implementations, the entire fringe pattern 239 does not fall on the active region 242 and/or the center portion of the active region 242 does not coincide with the center of the fringe pattern 239. This configuration results in the active region 242 capturing only portions of some of the fringes, and the partial fringes appear as partial rings in the data produced by the detector 240. In these implementations, accuracy may be improved by obtaining data from one or more complete fringes.

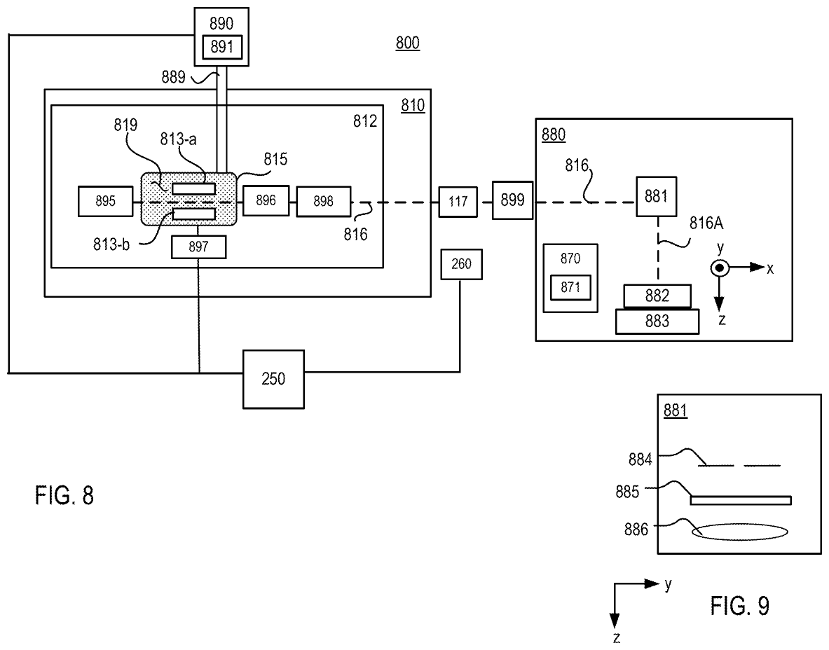

The electronic storage 252 also stores information about the etalon 230 or the optical system 181. For example, the electronic storage 252 may store a reference value of the property of the exposure light beam 112. In some implementations, the electronic storage 252 stores an actual or reference value of CBW derived from an optical spectrum of the exposure light beam 112 measured at the wafer 182 with a spectrometer (such as the spectrometer 871 of FIG. 8) or other optical instrument. The actual or reference value may be a numerical value that directly represents the CBW or an indication of the CBW, such as, for example, a first wavelength and a second wavelength that represent the endpoints of the FWHM of the measured optical spectrum of the exposure light beam 112.

The I/O interface 253 is any kind of interface that allows the estimation system 250 to exchange data and signals with an operator, other devices, and/or an automated process running on another electronic device. For example, in implementations in which data or instructions stored on the electronic storage 252 may be edited, the edits may be made through the I/O interface 253. In another example, the I/O interface 253 may be configured to output an estimate of a property of the exposure light beam 112 or an indication of such an estimate. The I/O interface 253 may include one or more of a visual display, a keyboard, and a communications interface, such as a parallel port, a Universal Serial Bus (USB) connection, and/or any type of network interface, such as, for example, Ethernet. The I/O interface 253 also may allow communication without physical contact through, for example, an IEEE 802.11, Bluetooth, or a near-field communication (NFC) connection.

The estimation system 250 is coupled to various components of the measurement system 260 through the data connection 254. The data connection 254 is any type of connection that allows transmission of data, signals, and/or information. For example, the data connection 254 may be a physical cable or other physical data conduit (such as a cable that supports transmission of data based IEEE 802.3), a wireless data connection (such as a data connection that provides data via IEEE 802.11 or Bluetooth), or a combination of wired and wireless data connections.

FIG. 3 is a flow chart of a process 300. The process 300 is used to determine an estimate of a property of the exposure light beam 112. The process 300 may be performed by the estimation system 250 (FIG. 2A). For example, the process 300 may be performed by one or more electronic processors in the processing module 251. The process 300 is discussed with respect to the estimation system 250 (FIG. 2A).

A set of values related to the initial light beam 116 is determined (310). The set of values is determined based on or from data produced by the detector 240. For example, the detector 240 may produce data that indicates the measured optical intensity of wavefronts of the portion 116′ incident on the active region 242. The data may be two-dimensional data that provides an indication of the distribution of optical energy over the active region 242. For example, the data may include a plurality of intensity values each of which is associated with a spatial coordinate, where the spatial coordinate indicates a portion of the active region 242. The data may include a representation of a fringe pattern formed from the portion 116′, such as the fringe pattern 239 (FIG. 2B).

The set of values includes two or more values that are related to the initial light beam 116. For example, in implementations in which the set of values is determined from data that represents the fringe pattern 239, the set of values may include a width of each of two or more of the fringes in the pattern 239. The width of a fringe is a spatial distance that represents the extent of the fringe between two adjacent regions of no light, such as the width 243 of FIG. 2C. The widths may be expressed as the FWHM of each fringe, or the width of each fringe at a pre-determined percentage of maximum intensity of the fringe. For example, the width of a fringe may be the width at 10% of the maximum intensity, or the width at 20% of maximum intensity. Different percentages may be used to determine the width of each fringe, or the same percentage may be used to determine the width of some or all of the fringes.

Moreover, more than one value in the set of values may be determined from the same fringe. For example, the set of values may include two values, with the first one of the values being the width of the first order fringe 239_1 at first percentage of the maximum intensity of the fringe 239_1 and the second one of the values being the width of the first order fringe 239_1 at second percentage of maximum intensity of the fringe 239_1. The first and second percentages are different percentages. For example, the first percentage may be 10% and the second percentage may be 90%, or any other percentage between 0% and 100% that is not equal to 90%.

The percentages used to determine the values in the set may be stored on the electronic storage 252. For example, in implementations that use fringe width to determine the values in the set, the electronic storage 252 may store an array or collection of pre-determined percentage values, with one of the percentage values being associated with each value in the set of values. In these implementations, if the set of values includes two fringe widths, the pre-determined percentage values may be stored in an array of two values that correspond to the percentage used for each fringe measurement. In some implementations, the pre-determined percentage values are entered by a user via the I/O interface 253.

A relationship that includes two or more values in the set of values is determined (320). In some implementations, the relationship is non-linear. The non-linear relationship may have a term for each of the two or more values, such as shown in Equation 1:

$$P = A ( V 1 ) + {B ( V 2 )}^{2} + … + {X ( Vn )}^{n} + cal , \qquad Equation ( 1 )$$

where P is the property of the exposure light beam 112; each of V1, V2, . . . , Vn is a value in the set of values determined at (310); n is an integer number that is equal to the number of values in the set of values; and cal, A, B, . . . X are calibrated parameters. In implementations in which the values in the set of values are fringe widths, each of V1, V2, . . . Vn is a fringe width determined as discussed above. For example, and continuing the example above, V1 may be the width of the first order fringe 239_1 at 10% of the peak or maximum intensity of the fringe 239_1 and V2 may be the width of the first order fringe 239_1 at 90% of the peak or maximum intensity of the fringe 239_1. The property P may be the CBW. Initial values of cal, A, B, . . . X are stored on the electronic storage 252 and/or entered by an operator via the I/O interface 253. The numerical values of cal, A, B, . . . X may represent, at least in part, optical properties of the optical system 181.

In some implementations, the relationship may be a more generalized nonlinear relationship, such as shown in Equation (1a)

$$P = {A ( V 1 )}^{k 1} + {B ( V 2 )}^{k 2} + … + {X ( Vn )}^{k n} + cal , \qquad Equation ( 1 a )$$

where k1, k2, . . . , kn are exponents used in modeling a CBW or other property P.

In some implementations, the relationship is a linear relationship, such as shown in Equation (2)

$$P = A ( V 1 ) + B ( V 2 ) + … + X ( Vn ) + cal , \qquad Equation ( 2 )$$

where P is the property of the exposure light beam 112; each of V1, V2, . . . , Vn is a value in the set of values determined at (310); n is an integer number that is equal to the number of values in the set of values; and cal, A, B, . . . X are calibrated parameters.

The property of the exposure light beam 112 is estimated based on the relationship (330). The initial values of cal, A, B, . . . X are used in Equation (1) or Equation (2) along with the values in the set of values to determine the estimate of the property P. Continuing the example above in which the relationship is a non-linear relationship, and the set of values includes two fringe width values (one of which is the width of the fringe 239_1 at 10% of maximum intensity and the other of which is the width of the fringe 239_1 at 90% of maximum intensity), the CBW is determined based on Equation (3)

$$CBW = A ( FW 1 ) + {B ( FW 2 )}^{2} + cal , \qquad Equation ( 3 )$$

where FW1 is the width of the fringe 239_1 at 10% of peak intensity; FW2 is the width of the fringe 239_1 at 90% of peak intensity; and A, B, and cal are the initial calibrated values obtained from the electronic storage 252 and/or through the I/O interface 253.

The estimated property of the exposure light beam 112 may be output by the I/O interface 253. For example, the estimated property of the exposure light beam 112 may be output as a numerical value that is visually presented at a display, at a device that is remote from the estimation system 250, and/or stored as a value in the electronic storage 252.

In some implementations the process 300 ends after estimating the property in (330). In some implementations, the process 300 returns to (310) after estimating the property in (330) such that changes that may occur during operation of the system 200 are accounted for by estimating the property of the exposure light beam 112 during operation of the system 200.

In some implementations, the estimated property is stored as an initial estimate, and the process 300 continues to (340). A reference value of the same property is accessed (340). The reference value of the property is a measured or mathematically determined value of the property that is known to be accurate. For example, if the CBW of the exposure light beam 112 was estimated at (330), then a reference value of the CBW of the exposure light beam 112 is accessed. In this example, the optical spectrum is directly measured with a spectrometer positioned at the wafer 182, and the reference value is a CBW value that is determined from the measured optical spectrum. The estimate and the reference value may be accessed from the electronic storage 252 and/or received through the I/O interface 253.

The estimated property of the exposure light beam 112 is compared to the reference value to determine how well the estimate fits the reference value (350). For example, the absolute value of the difference between the estimate of the property and the reference value may be determined and compared to a threshold. In this example, the threshold is a numerical value that is stored on the electronic storage 252 and/or is provided through the I/O interface 253. The threshold may be any value equal to or greater than zero.

The estimated property is assessed for acceptability based on the comparison (360). If the absolute value of the difference is less than or equal to the threshold, then the estimated value of the property is acceptable, the process 300 ends or returns to (310) to continue monitoring the property of the exposure light beam 112. If the absolute value of the difference is greater than the threshold, then the estimated value of the property is not acceptable, and a minimization and/or optimization technique is initiated (370) to reduce the error in the estimate of the value of the property.

In the example of FIG. 3, the values of the parameters A, B, . . . X, and cal that minimize the difference between the initial estimated property and the reference value of the property given the values in the set of values are determined using an optimization or minimization technique (370). Any optimization and/or minimization technique may be used to determine the value of the parameters that minimize the difference. For example, in implementations in which the set of values includes two values and the non-linear relationship is a second-order equation (such as shown in Equation 3), a quadratic optimization may be used to determine the values of A, B, and cal that minimize the difference between the estimated value of the property and the reference value. After determining the value of the parameters A, B, . . . , X, and cal that minimize the difference, the process 300 ends or returns to (310) to continue estimating the property of the exposure light beam 112.

Aspects of the process 300 also may be used to determine the pre-determined percentage values that are applied to the data from the detector 240 to determine the set of values in (310). As discussed above, the set of values may be a collection of fringe widths, where each fringe width is measured at a particular percentage of the maximum intensity of the fringe. The pre-determined percentage values are determined prior to the process 300 being performed, and the pre-determined percentage values may be those percentages that are known, through empirical analysis and/or mathematical analysis, to produce the best or acceptable results.

For example, the pre-determined percentages may be those percentages that are known or expected to provide the best estimate of the CBW. To determine the pre-determined percentage values, CBW is estimated using Equation (1) or Equation (2) using the initial values of A, B, . . . , X, and cal and fringe width values (V1, V2, . . . VN) that are based on many possible percentage values. The error between the estimated CBW and the reference CBW for each possible percentage value is determined, and the percentage or percentages that produce the smallest error are selected and stored as the pre-determined percentage values. The process 300 is then performed with those pre-determined percentage values and the values of A, B, . . . , X, and cal are optimized at (360).

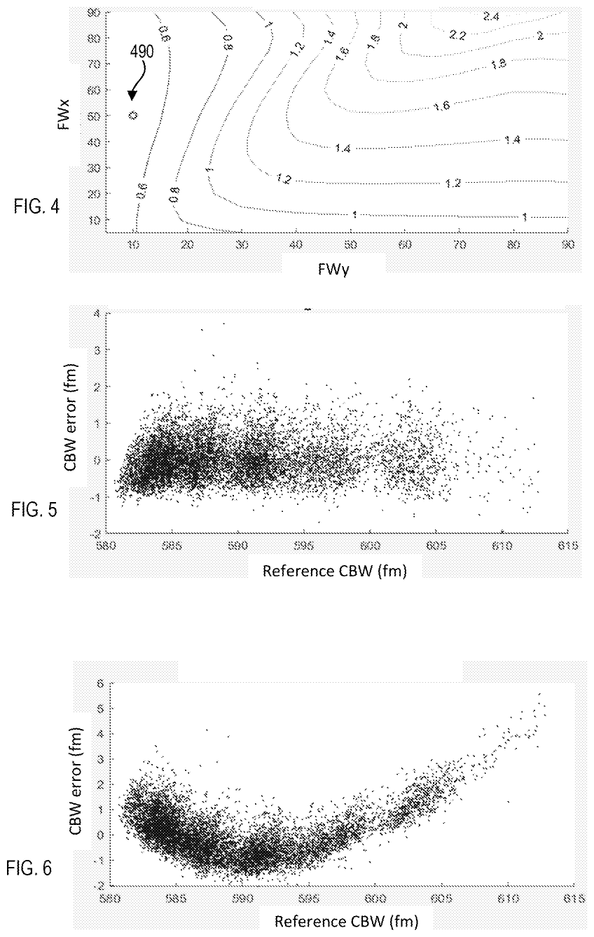

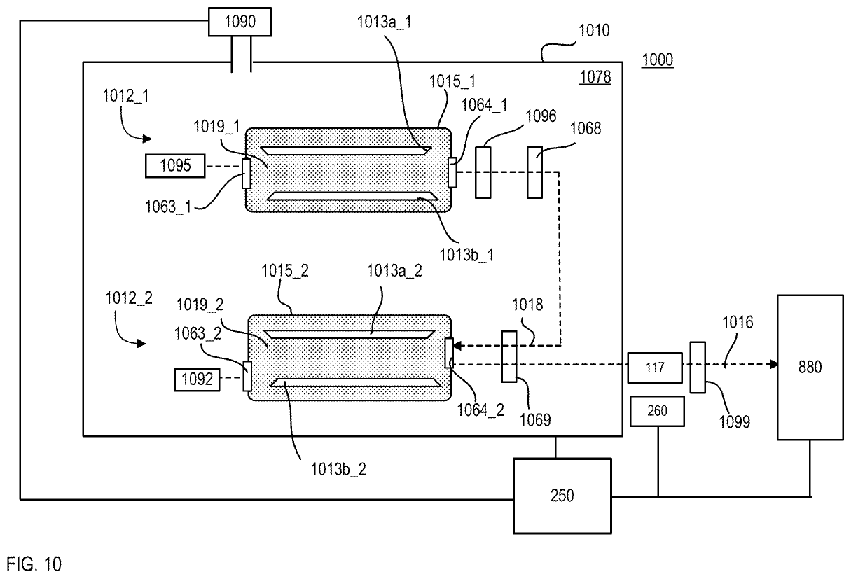

FIG. 4 is an example of CBW estimation error for a second order non-linear relationship (such as in Equation (3)) for many different fringe width percentage values. The data shown in FIG. 4 is experimental data that was generated with a two-stage master oscillator power amplifier (MOPA) laser such as the light-generation module 1010 shown in FIG. 10. The parameters of the light-generation module 1010 were varied to scan CBW over its full operating range. The timing of the excitation of the electrodes in the master oscillator (MO) 1012_1 relative to the timing of the excitation of the electrodes in the power amplifier (PA) 1012_2, the repetition rate, and the angle of a prism in the line narrowing module 1095 were varied to obtain the full range of CBW values. In FIG. 4, the y-axis is the first fringe width percentage value, the x-axis is the second fringe width percentage value, and the contour lines represent the minimum mean squared error in the CBW estimate as a function of the first and second fringe width percentage values. The fringe width percentage values that correspond to the lowest CBW error are selected. In the example shown, the CBW error is minimized by setting the first fringe width percentage value to about 50% and the second fringe width percentage value to about 10%. The point corresponding to these percentage values is labeled 490 in FIG. 4. The process 300 is performed after selecting the pre-determined percentage values.

Other approaches for setting the pre-determined percentage values before performing the process 300 are possible. For example, the pre-determined percentage values may be random or may be set to a certain initial value, such as 50%. In these implementations, the error in the initial CBW estimate is reduced by performing the optimization (370) as part of the process 300.

FIG. 5 is the error in the CBW estimate (in femtometers) as a function of a measured reference CBW (in femtometers) when a second-order relationship such as shown in Equation (3) was used to estimate CBW, with FW1 being the fringe width of the fringe nearest to the center of the ring of fringes at 10% intensity and FW2 being the fringe width of the fringe nearest to the center of the ring of fringes at 40% intensity. The reference CBW was measured with an external spectrometer. FIG. 6 shows the error in the CBW estimate (in femtometers) as a function of a measured reference CBW (in femtometers) when a linear relationship such as shown in Equation (2) was used to estimate CBW. The error for the CBW estimated with the second-order relationship (FIG. 5) has a smaller maximum value and a smaller standard deviation as compared to the error in the CBW estimated with the linear relationship (FIG. 6). For example, the maximum error for the CBW error in the second-order approach is about 4, and the maximum error in the linear approach is about 6. Although the CBW may be estimated using the linear relationship, FIGS. 5 and 6 show that the second-order relationship (FIG. 5) provides a more accurate estimate of the CBW with only a modest increase in complexity. The maximum error and the standard deviation of the error in the CBW estimate may be reduced further (for example, by an additional 10% or less) by using a higher-order polynomial (for example n=3 or n=4 in Equation 1).

Each of FIGS. 7A-7C show simulated data of estimated CD as a function of an estimated spectral bandwidth metric (in femtometers (fm)) for seven different exposure tools. FIG. 7A shows CD as a function of a FWHM metric. FIG. 7B shows CD as a function of an E95 metric. FIG. 7C shows CD as a function of CBW. As shown in FIG. 7C, the CBW and CD are linearly correlated for all seven of the exposure tools. Moreover, when CBW is the metric, the characteristics of the linear correlation (for example, the slope of the line fit to the CD value when plotted as a function of CBW) is similar for all seven of the exposure tools. Although CD is linearly correlated with the FWHM metric (FIG. 7A) and the E95 metric (FIG. 7B), there is variation in the characteristics of the correlation between CD and the FWHM and E95 metrics among the different tools. FIGS. 7A-7C show that CBW has the best correlation with CD across different exposure tools. Thus, CBW is a robust metric that may be used to monitor and/or adjust performance on different machines.

FIGS. 8 and 10 are examples of deep ultraviolet (DUV) optical systems with which the measurement system 160 or 260 may be used. In the examples below, the measurement system 260 is shown as used with a DUV optical system.

Referring to FIGS. 8 and 9, a system 800 includes a light-generation module 810 that provides an exposure light beam (or output light beam) 816 to a scanner apparatus 880, which includes a projection optical system 881. In various implementations, the transfer function of the optical system 181 may be transfer function of the scanner apparatus 880 or a transfer function of one or more portions of the scanner apparatus, such as the projection optical system 881. The light-generation module 810 and the projection optical system 881 are implementations of the light-generation module 110 and the optical system 181, respectively (FIG. 1A).

The system 800 also includes the beam separator 117, the measurement system 260, and the estimation system 250. The beam separator 117 directs a portion of the exposure light beam 816 to the measurement system 260 that is used to measure the wavelength of the exposure light beam 816. The estimation system 250 is coupled to the measurement system 260. In the example of FIG. 8, the estimation system 250 is also coupled to the light-generation module 810 and to various components associated with the light-generation module 810.

The light-generation module 810 includes an optical oscillator 812. The optical oscillator 812 generates the output light beam 816. The optical oscillator 812 includes a discharge chamber 815, which encloses a cathode 813-a and an anode 813-b. The discharge chamber 815 also contains a gaseous gain medium 819. A potential difference between the cathode 813-a and the anode 813-b forms an electric field in the gaseous gain medium 819. The potential difference may be generated by controlling a voltage source 897 to apply voltage to the cathode 813-a and/or the anode 813-b. The electric field provides energy to the gain medium 819 sufficient to cause a population inversion and to enable generation of a pulse of light via stimulated emission. Repeated creation of such a potential difference forms a train of pulses, which are emitted as the light beam 816. The repetition rate of the pulsed light beam 816 is determined by the rate at which voltage is applied to the electrodes 813-a and 813-b.

The gain medium 819 is pumped by applying of a voltage to the electrodes 813-a and 813-b. The duration and repetition rate of the pulses in the pulsed light beam 816 is determined by the duration and repetition rate of the application of the voltage to the electrodes 813-a and 813-b. The repetition rate of the pulses may range, for example, between about 500 and 6,000 Hz. In some implementations, the repetition rate may be greater than 6,000 Hz, and may be, for example, 12,000 Hz or greater. Each pulse emitted from the optical oscillator 812 may have a pulse energy of, for example, approximately 1 milliJoule (mJ).

The gaseous gain medium 819 may be any gas suitable for producing a light beam at the wavelength, energy, and bandwidth required for the application. The gaseous gain medium 819 may include more than one type of gas, and the various gases are referred to as gas components. For an excimer source, the gaseous gain medium 819 may contain a noble gas (rare gas) such as, for example, argon or krypton; or a halogen, such as, for example, fluorine or chlorine. In implementations in which a halogen is the gain medium, the gain medium also includes traces of xenon apart from a buffer gas, such as helium.

The gaseous gain medium 819 may be a gain medium that emits light in the deep ultraviolet (DUV) range. DUV light may include wavelengths from, for example, about 100 nanometers (nm) to about 400 nm. Specific examples of the gaseous gain medium 819 include argon fluoride (ArF), which emits light at a wavelength of about 193 nm, krypton fluoride (KrF), which emits light at a wavelength of about 248 nm, or xenon chloride (XeCl), which emits light at a wavelength of about 351 nm.

A resonator is formed between a spectral adjustment apparatus 895 on one side of the discharge chamber 815 and an output coupler 896 on a second side of the discharge chamber 815. The spectral adjustment apparatus 895 may include a diffractive optic such as, for example, a grating and/or a prism, that finely tunes the spectral output of the discharge chamber 815. The diffractive optic may be reflective or refractive. In some implementations, the spectral adjustment apparatus 895 includes a plurality of diffractive optical elements. For example, the spectral adjustment apparatus 895 may include four prisms, some of which are configured to control a center wavelength of the light beam 816 and others of which are configured to control a spectral bandwidth of the light beam 816.

The spectral properties of the light beam 816 may be adjusted in other ways. For example, the spectral properties, such as the spectral bandwidth and center wavelength, of the light beam 816 may be adjusted by controlling a pressure and/or gas concentration of the gaseous gain medium of the chamber 815. For implementations in which the light-generation module 810 is an excimer source, the spectral properties (for example, the spectral bandwidth or the center wavelength) of the light beam 816 may be adjusted by controlling the pressure and/or concentration of, for example, fluorine, chlorine, argon, krypton, xenon, and/or helium in the chamber 815.

The pressure and/or concentration of the gaseous gain medium 819 is controllable with a gas supply system 890. The gas supply system 890 is fluidly coupled to an interior of the discharge chamber 815 via a fluid conduit 889. The fluid conduit 889 is any conduit that is capable of transporting a gas or other fluid with no or minimal loss of the fluid. For example, the fluid conduit 889 may be a pipe that is made of or coated with a material that does not react with the fluid or fluids transported in the fluid conduit 889. The gas supply system 890 includes a chamber 891 that contains and/or is configured to receive a supply of the gas or gasses used in the gain medium 819. The gas supply system 890 also includes devices (such as pumps, valves, and/or fluid switches) that enable the gas supply system 890 to remove gas from or inject gas into the discharge chamber 815. The gas supply system 890 is coupled to the estimation system 250.

The optical oscillator 812 also includes a spectral analysis apparatus 898. The spectral analysis apparatus 898 is a measurement system that may be used to measure or monitor the wavelength of the light beam 816. In the example shown in FIG. 8, the spectral analysis apparatus 898 receives light from the output coupler 896. In some implementations, the spectral analysis apparatus 898 is part of the measurement system 260.

The light-generation module 810 may include other components and systems. For example, the light-generation module 810 may include a beam preparation system 899. The beam preparation system 899 may include a pulse stretcher that stretches each pulse that interacts with the pulse stretcher in time. The beam preparation system also may include other components that are able to act upon light such as, for example, reflective and/or refractive optical elements (such as, for example, lenses and mirrors), and/or filters. In the example shown, the beam preparation system 899 is positioned in the path of the exposure light beam 816. However, the beam preparation system 899 may be placed at other locations within the system 800.

The system 800 also includes the scanner apparatus 880. The scanner apparatus 880 exposes a wafer 882 with a shaped exposure light beam 816A. The shaped exposure light beam 816A is formed by passing the exposure light beam 816 through a projection optical system 881. The scanner apparatus 880 may be a liquid immersion system or a dry system. The scanner apparatus 880 includes a projection optical system 881 through which the exposure light beam 816 passes prior to reaching the wafer 882, and a sensor system or metrology system 870. The wafer 882 is held or received on a wafer holder 883. The scanner apparatus 880 also may include, for example, temperature control devices (such as air conditioning devices and/or heating devices), and/or power supplies for the various electrical components.

The metrology system 870 includes a sensor 871. The sensor 871 may be configured to measure a property of the shaped exposure light beam 816A such as, for example, bandwidth, energy, pulse duration, and/or wavelength. The sensor 871 may be, for example, a camera or other device that is able to capture an image of the shaped exposure light beam 816A at the wafer 882, or an energy detector that is able to capture data that describes the amount of optical energy at the wafer 882 in the x-y plane. The sensor 871 may be a spectrometer that determines the optical spectrum of the exposure light beam 816A.

Referring also to FIG. 9, the projection optical system 881 includes a slit 884, a mask 885, and a projection objective, which includes a lens system 886. The lens system 886 includes one or more optical elements. The exposure light beam 816 enters the scanner apparatus 880 and impinges on the slit 884, and at least some of the output light beam 816 passes through the slit 884 to form the shaped exposure light beam 816A. In the example of FIGS. 8 and 9, the slit 884 is rectangular and shapes the exposure light beam 816 into an elongated rectangular shaped light beam, which is the shaped exposure light beam 816A. The mask 885 includes a pattern that determines which portions of the shaped light beam are transmitted by the mask 885 and which are blocked by the mask 885. Microelectronic features are formed on the wafer 882 by exposing a layer of radiation-sensitive photoresist material on the wafer 882 with the exposure light beam 816A. The design of the pattern on the mask is determined by the specific microelectronic circuit features that are desired.

The configuration shown in FIG. 8 is an example of a configuration for a DUV system. Other implementations are possible, and the estimation system 250 may be used with other implementations of the light-generation module 810.

For example, the light-generation module 810 may include N instances of the optical oscillator 812 arranged in parallel, where N is an integer number greater than one. In these implementations, each optical oscillator 812 is configured to emit a respective light beam toward a beam combiner, which forms the exposure light beam 816 from the beam emitted by one or more of the N oscillators.

In another example, and referring to FIG. 10, the light-generation module 810 may be configured as a multi-stage laser system. For example, the light-generation module 810 may be a two-stage laser system that includes a master oscillator (MO) that provides a seed light beam to a power amplifier (PA), which amplifies the seed light beam to generate the output light beam 816. Such a laser system may be referred to as a MOPA laser system.

FIG. 10 shows another example configuration of a DUV system. FIG. 10 is a block diagram of a photolithography system 1000 that includes a light-generation module 1010 that produces a pulsed light beam 1016, which is provided to the scanner apparatus 880. The photolithography system 1000 also includes the beam separator 117, the measurement system 260, and the estimation system 250. The estimation system 250 is coupled to the measurement system 260, various components of the light-generation module 1010, and the scanner apparatus 1080 to control various operations of the system 1000. In the example of FIG. 10, the beam separator 117 directs a portion of the output light beam 1016 to the measurement system 260.

The light-generation module 1010 is a two-stage laser system that includes a master oscillator (MO) 1012_1 that provides the seed light beam 1018 to a power amplifier (PA) 1012_2. The PA 1012_2 receives the seed light beam 1018 from the MO 1012_1 and amplifies the seed light beam 1018 to generate the light beam 1016 for use in the scanner apparatus 880. For example, in some implementations, the MO 1012_1 may emit a pulsed seed light beam, with seed pulse energies of approximately 1 milliJoule (mJ) per pulse, and these seed pulses may be amplified by the PA 1012_2 to about 10 to 15 mJ, but other energies may be used in other examples.

The MO 1012_1 includes a discharge chamber 1015_1 having two elongated electrodes 1013a_1 and 1013b_1, a gain medium 1019_1 that is a gas mixture, and a fan (not shown) for circulating the gas mixture between the electrodes 1013a_1, 1013b_1. A resonator is formed between a line narrowing module 1095 on one side of the discharge chamber 1015_1 and an output coupler 1096 on a second side of the discharge chamber 1015_1.

The discharge chamber 1015_1 includes a first chamber window 1063_1 and a second chamber window 1064_1. The first and second chamber windows 1063_1 and 1064_1 are on opposite sides of the discharge chamber 1015_1. The first and second chamber windows 1063_1 and 1064_1 transmit light in the DUV range and allow DUV light to enter and exit the discharge chamber 1015_1.

The line narrowing module 1095 may include one or more diffractive optics such as a grating or prism that finely tunes the spectral output of the discharge chamber 1015_1. The light-generation module 1010 also includes a line center analysis module 1068 that receives an output light beam from the output coupler 1096 and a beam coupling optical system 1069. The line center analysis module 1068 is a measurement system that may be used to measure or monitor the wavelength of the seed light beam 1018. The line center analysis module 1068 may be placed at other locations in the light-generation module 1010, or it may be placed at the output of the light-generation module 1010.

The gas mixture that is the gain medium 1019_1 may be any gas suitable for producing a light beam at the wavelength and bandwidth required for the application. For an excimer source, the gas mixture may contain a noble gas (rare gas) such as, for example, argon or krypton, a halogen, such as, for example, fluorine or chlorine and traces of xenon apart from a buffer gas, such as helium. Specific examples of the gas mixture include argon fluoride (ArF), which emits light at a wavelength of about 193 nm, krypton fluoride (KrF), which emits light at a wavelength of about 248 nm, or xenon chloride (XeCl), which emits light at a wavelength of about 351 nm. Thus, the light beams 1016 and 1018 include wavelengths in the DUV range in this implementation. The excimer gain medium (the gas mixture) is pumped with short (for example, nanosecond) current pulses in a high-voltage electric discharge by application of a voltage to the elongated electrodes 1013a_1, 1013b_1.

The PA 1012_2 includes a beam coupling optical system 1069 that receives the seed light beam 1018 from the MO 1012_1 and directs the seed light beam 1018 through a discharge chamber 1015_2, and to a beam turning optical element 1092, which modifies or changes the direction of the seed light beam 1018 so that it is sent back into the discharge chamber 1015_2. The beam turning optical element 1092 and the beam coupling optical system 1069 form a circulating and closed loop optical path in which the input into a ring amplifier intersects the output of the ring amplifier at the beam coupling optical system 1069.

The discharge chamber 1015_2 includes a pair of elongated electrodes 1013a_2, 1013b_2, a gain medium 1019_2, and a fan (not shown) for circulating the gain medium 1019_2 between the electrodes 1013a_2, 1013b_2. The gas mixture that forms the gain medium 1019_2 may be the same as the gas mixture that forms gain medium 1019_1.

The discharge chamber 1015_2 includes a first chamber window 1063_2 and a second chamber window 1064_2. The first and second chamber windows 1063_2 and 1064_2 are on opposite sides of the discharge chamber 1015_2. The first and second chamber windows 1063_2 and 1064_2 transmit light in the DUV range and allow DUV light to enter and exit the discharge chamber 1015_2.

When the gain medium 1019_1 or 1019_2 is pumped by applying voltage to the electrodes 1013a_1, 1013b_1 or 1013a_2, 1013b_2, respectively, the gain medium 1019_1 and/or 1019_2 emits light. When voltage is applied to the electrodes at regular temporal intervals, the light beam 1016 is pulsed. Thus, the repetition rate of the pulsed light beam 1016 is determined by the rate at which voltage is applied to the electrodes. The repetition rate of the pulses may range between about 500 and 6,000 Hz for various applications. In some implementations, the repetition rate may be greater than 6,000 Hz, and may be, for example, 12,000 Hz or greater, but other repetition rates may be used in other implementations. Additionally a controller (which may be implemented as part of the estimation system 250) controls the timing of the application of voltage to the electrodes 1013a_1, 1013b_1 relative to the application of voltage to the electrodes 1013a_2, 1013b_2 such that the gain medium 1019_2 is excited at an appropriate time to ensure that the seed light beam 1018 is amplified.

The output light beam 1016 may be directed through a beam preparation system 1099 prior to reaching the scanner apparatus 880. The beam preparation system 1099 may include a bandwidth analysis module that measures various parameters (such as the bandwidth or the wavelength) of the beam 1016. The beam preparation system 1099 also may include a pulse stretcher that stretches each pulse of the output light beam 1016 in time. The beam preparation system 1099 also may include other components that are able to act upon the beam 1016 such as, for example, reflective and/or refractive optical elements (such as, for example, lenses and mirrors), filters, and optical apertures (including automated shutters).

The DUV light-generation module 1010 also includes the gas management system 1090, which is in fluid communication with an interior 1078 of the DUV light-generation module 1010.

The implementations and/or embodiments can be further described using the following clauses.
1. An apparatus comprising:
an estimation system configured to:
determine a set of values related to an initial light beam based on sensed wavefronts of the initial light beam, the set of values comprising a first value and a second value; and
determine an estimate of a property of an exposure light beam based on a non-linear relationship that comprises the first value and the second value, wherein the exposure light beam is formed by interacting the initial light beam with an optical system; and
a communications module coupled to the estimation system and configured to output the estimate of the property of the exposure light beam.
2. The apparatus of clause 1, wherein the property of the exposure light beam comprises a convolved bandwidth metric, the convolved bandwidth metric representing a width of a portion of an optical spectrum of the exposure light beam at a wafer that is irradiated by the exposure light beam; and the optical spectrum of the exposure light beam comprises intensity of the exposure light beam as a function of wavelength.
3. The apparatus of clause 1, wherein the sensed wavefronts of the initial light beam comprise a fringe pattern produced from the initial light beam; the fringe pattern comprises a plurality of fringes; the first value comprises a first width of a first one of the plurality of fringes; and the second value comprises a second width of a second one of the plurality of fringes.
4. The apparatus of clause 3, wherein the first one of the plurality of fringes and the second one of the plurality of fringes are the same one fringe.
5. The apparatus of clause 4, wherein the first width is a width of the one fringe at a first percentage of a peak intensity of the one fringe; and the second width is a width of the one fringe at a second percentage of the peak intensity of the one fringe.
6. The apparatus of clause 5, wherein the first percentage and the second percentage are different percentages.
7. The apparatus of clause 6, wherein the plurality of fringes are concentric rings of light centered around a center point and separated by regions of no light; and the one fringe is the fringe closest to the center point.
8. The apparatus of clause 1, wherein the non-linear relationship comprises a second-order relationship.
9. The apparatus of clause 8, wherein one of the first value and the second value is squared.
10. The apparatus of clause 1, wherein the non-linear relationship further comprises a plurality of calibration parameters.
11. The apparatus of clause 10, wherein the estimation system is further configured to:
access a reference value of the property of the exposure light beam; and
determine values for each of the calibration parameters by minimizing a difference between the estimate of the property and the reference value of the property.
12. The apparatus of clause 11, wherein the reference value of the property is obtained by a spectrometer.
13. The apparatus of clause 1, further comprising the optical system.
14. The apparatus of clause 1, wherein the optical system comprises projection lens and a reticle.
15. The apparatus of clause 3, further comprising an etalon configured to produce the fringe pattern.
16. The apparatus of clause 1, further comprising a detector configured to sense the wavefronts and to provide data related to the sensed wavefronts to the estimation system.
17. A system comprising:
a light source configured to emit a light beam comprising deep ultraviolet (DUV) light;
an optical measurement system configured to produce a fringe pattern based on the light beam;
a projection optical system configured emit an exposure light beam based on the light beam; and
an estimation system configured to:
determine a first value and a second value from the fringe pattern; and
determine an estimate of a property of the exposure light beam based on the first value and the second value.
18. The system of clause 17, wherein the projection optical system comprises a projection lens and a reticle.
19. The system of clause 17, wherein the estimation system is configured to determine the estimate of the property based on a non-linear relationship; and the non-linear relationship comprises the first value, the second value, and a plurality of calibration constants.
20. The system of clause 19, wherein the estimation system is further configured to:
determine a value for each of the plurality of calibration constants based on minimizing a difference between the estimate of the property and a reference value of the property.
21. The system of clause 17, wherein the optical measurement system comprises an etalon.
22. The system of clause 17, wherein the light source comprises a master oscillator configured to emit a seed light beam, and a power amplifier configured to amplify the seed light beam to produce the light beam comprising DUV light.
23. A method comprising:
sensing wavefronts of an initial light beam;
determining a set of values of an initial light beam based on the sensed wavefronts;
determining a relationship that comprises at least two of values in the set of values; and
determining an estimate of a property of an exposure light beam based on the relationship, wherein the exposure light beam is produced by interacting the initial light beam with an optical system.
24. The method of clause 23, wherein the relationship is a non-linear relationship.

Other implementations are within the scope of the claims.

1. An apparatus comprising:
an estimation system configured to:
determine a set of values related to an initial light beam based on sensed wavefronts of the initial light beam, the set of values comprising a first value and a second value; and
determine an estimate of a property of an exposure light beam based on a non-linear relationship that comprises the first value and the second value, wherein the exposure light beam is formed by interacting the initial light beam with an optical system; and
a communications module coupled to the estimation system and configured to output the estimate of the property of the exposure light beam.

2. The apparatus of claim 1, wherein the property of the exposure light beam comprises a convolved bandwidth metric, the convolved bandwidth metric representing a width of a portion of an optical spectrum of the exposure light beam at a wafer that is irradiated by the exposure light beam; and the optical spectrum of the exposure light beam comprises intensity of the exposure light beam as a function of wavelength.

3. The apparatus of claim 1, wherein the sensed wavefronts of the initial light beam comprise a fringe pattern produced from the initial light beam; the fringe pattern comprises a plurality of fringes; the first value comprises a first width of a first one of the plurality of fringes; and the second value comprises a second width of a second one of the plurality of fringes.

4. The apparatus of claim 3, wherein the first one of the plurality of fringes and the second one of the plurality of fringes are the same one fringe.

5. The apparatus of claim 4, wherein the first width is a width of the one fringe at a first percentage of a peak intensity of the one fringe; and the second width is a width of the one fringe at a second percentage of the peak intensity of the one fringe.

6. The apparatus of claim 5, wherein the first percentage and the second percentage are different percentages.

7. The apparatus of claim 6, wherein the plurality of fringes are concentric rings of light centered around a center point and separated by regions of no light; and the one fringe is the fringe closest to the center point.

8. The apparatus of claim 1, wherein the non-linear relationship comprises a second-order relationship.

9. (canceled)

10. (canceled)

11. The apparatus of claim 1, wherein the estimation system is further configured to:
access a reference value of the property of the exposure light beam; and
determine values for each of a plurality of calibration parameters by minimizing a difference between the estimate of the property and the reference value of the property.

12. The apparatus of claim 11, wherein the reference value of the property is obtained by a spectrometer.

13. (canceled)

14. (canceled)

15. The apparatus of claim 3, further comprising an etalon configured to produce the fringe pattern.

16. The apparatus of claim 1, further comprising a detector configured to sense the wavefronts and to provide data related to the sensed wavefronts to the estimation system.

17. A system comprising:
a light source configured to emit a light beam;
an optical measurement system configured to produce a fringe pattern based on the light beam;
a projection optical system configured emit an exposure light beam based on the light beam; and
an estimation system configured to:
determine a first value and a second value from the fringe pattern; and
determine an estimate of a property of the exposure light beam based on the first value and the second value.

18. (canceled)

19. The system of claim 17, wherein the estimation system is configured to determine the estimate of the property based on a non-linear relationship; and the non-linear relationship comprises the first value, the second value, and a plurality of calibration constants.

20. The system of claim 19, wherein the estimation system is further configured to:
determine a value for each of the plurality of calibration constants based on minimizing a difference between the estimate of the property and a reference value of the property.

21. (canceled)

22. The system of claim 17, wherein the light source comprises a master oscillator configured to emit a seed light beam, and a power amplifier configured to amplify the seed light beam to produce the light beam comprising deep ultraviolet (DUV) light.

23. A method comprising:
sensing wavefronts of an initial light beam;
determining a set of values of an initial light beam based on the sensed wavefronts;
determining a non-linear relationship that comprises at least two of values in the set of values; and
determining an estimate of a property of an exposure light beam based on the non-linear relationship, wherein the exposure light beam is produced by interacting the initial light beam with an optical system.

24. (canceled)

25. The method of claim 23, wherein determining the set of values of the initial light beam comprises:
obtaining a first value from a first width of a first one of a plurality of fringes; and
obtaining a second value from a second width of a second one of the plurality of fringes.

26. The method of claim 25, wherein the first one fringe is a first order fringe of the plurality of fringes and the second one fringe is a second order fringe of the plurality of fringes.

27. The method of claim 25, wherein the first width is a width of the first one fringe at a first percentage of a peak intensity of the first one fringe, the second width is a width of the second one fringe at a second percentage of a peak intensity of the second one fringe, and the first percentage is smaller than the second percentage.
